(19) United States
(12) Patent Application Publication
(10) Pub. No.: US 2009/0284215 A1
(43) Pub. Date: Nov. 19, 2009

(54) PORTABLE ELECTRONIC DEVICE HAVING SOLAR CELL

(75) Inventor: TAI-HSU CHOU, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/417,863

(22) Filed: Apr. 3, 2009

(30) Foreign Application Priority Data
May 16, 2008 (CN) 200810301608.2

(51) Int. Cl. H02J 7/00; H01L 33/00

(52) U.S. Cl. 320/101; 257/461; 257/E33.045

(57) ABSTRACT

A portable electronic device includes a shell, a powering circuit, and solar cell. The shell includes a transparent section. The powering circuit is fixed in the shell and located facing the transparent section. The solar cell is connected to the powering circuit. When exterior light irradiates the transparent section, the solar cell converts the absorbed light into electrical voltage which is supplied to the portable electronic device to power functions thereof.

### BACKGROUND

1. Technical Field

The disclosure generally relates to portable electronic devices, and particularly to a portable electronic device utilizing a solar cell.

2. Description of Related Art

As electronic technology develops, portable electronic devices such as mobile phones and laptops are commonly in use. A portable electronic device often includes a main body and a rechargeable battery. The rechargeable battery supplies power for the device to function. The rechargeable battery can be charged many times by a charger using an alternating current (AC) power source. Conventional rechargeable batteries include nickel-cadmium (Ni—Cd) batteries, nickel-hydrogen (Ni—H) batteries, lithium ion (Li-ion) batteries, and others. These rechargeable batteries can be recharged after each discharge again and again.

In general, a specific electronic device can only use a specific corresponding kind of rechargeable battery which can be charged only with a dedicated charger. The rechargeable battery of the device cannot be charged without the corresponding charger. Accordingly, if for example the charger is misplaced, the rechargeable battery may not be able to be timely recharged. In such circumstances, the user is liable to be inconvenienced.

What is needed, therefore, is a portable electronic device addressing the limitations described.

### BRIEF DESCRIPTION OF THE DRAWINGS

FIG. 1 is a perspective view of a portable electronic device utilizing a solar cell in accordance with a first embodiment.

FIG. 2 is an enlarged, schematic cross-section of the solar cell of FIG. 1.

FIG. 3 is a block diagram of a powering circuit of the electronic device of FIG. 1.

FIG. 4 is a perspective view of a portable electronic device utilizing a solar cell in accordance with a second embodiment.

### DETAILED DESCRIPTION OF EMBODIMENTS

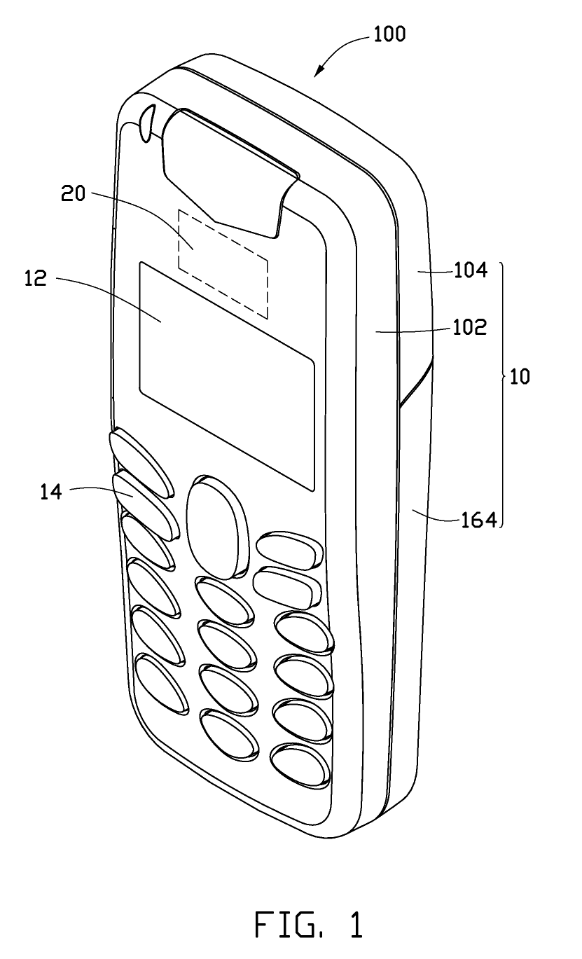

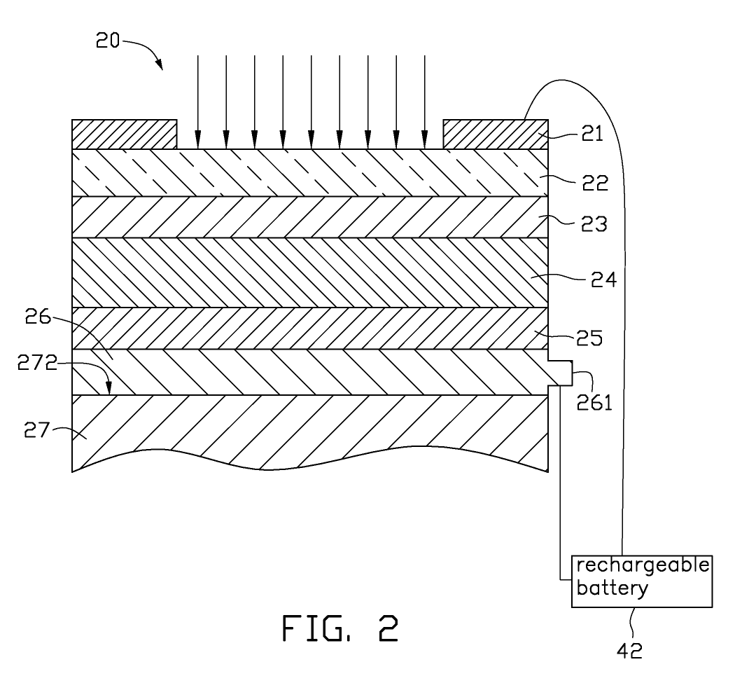

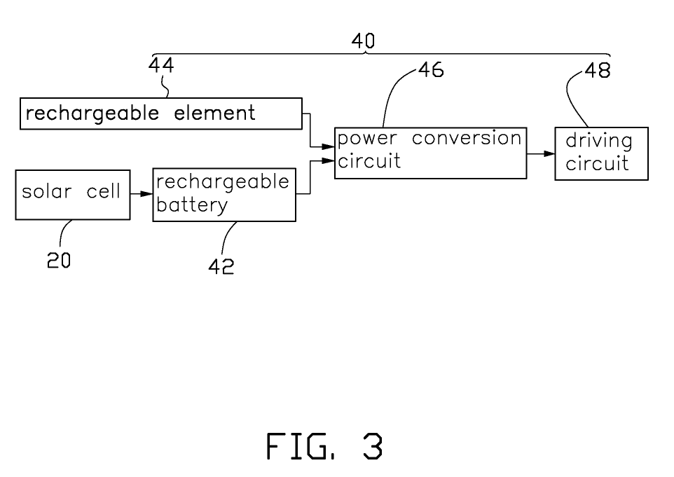

Referring to FIGS. 1-3, a first embodiment of a portable electronic device utilizing a solar cell in accordance with the disclosure includes a shell 10, a display screen 12, a keypad 14, a solar cell 20, and a powering circuit 40. Here, the portable electronic device is a mobile phone 100. The portable electronic device can also be a laptop, a personal digital assistant (PDA), or any of various other kinds of portable electronic devices.

The shell 10 includes a front cover 102, a back cover 104, and a cell cover 164. The cell cover 164 and the back cover 104 are adjacent to each other, and connected with the front cover 102 to cooperatively form a housing of the mobile phone 100. The shell 10 defines a highly transparent section. Here, the highly transparent section is defined on the front cover 102. The front cover 102 is a highly transparent material, such as transparent resin, polymethyl methacrylate, or polyepoxy compound. The back cover 104 is an opaque material, such as plastic or metal. The material of the cell cover 164 can be same as that of the back cover 104. The powering circuit 40 and the solar cell 20 are secured in the housing of the mobile phone 100. The solar cell 20 is located facing the front cover 102.

The display screen 12 is disposed on the upper portion of the front cover 102. The display screen 12 is configured for displaying figures, letters, images or other contents. The display screen 12 can be a liquid crystal display or a light-emitting diode display. The keypad 14 (i.e., the input module) is disposed generally on the lower portion of the front cover 102. The keypad 14 is configured for accepting input of user-selected signals such as dialed numbers, data entry, and so on.

The front cover 102 is configured for absorbing sunlight or other ambient light. When the light irradiates the front cover 102, the solar cell 20 converts the absorbed light into electrical voltage. The electrical voltage is then stored in the solar cell 20. The solar cell 20 is configured for supplying electrical voltage to components within the mobile phone 100 to power the functions of the mobile phone 100.

The solar cell 20 includes a substrate 27 having a first surface 272. A back electrode layer 26 is formed on the first surface 272 of the substrate 27. A p-type semiconductor layer 25 is formed on the back electrode layer 26. A p-n junction layer 24 is formed on the p-type semiconductor layer 25. An n-type semiconductor layer 23 is formed on the p-n junction layer 24. A transparent conductive layer 22 is formed on the n-type semiconductor layer 23. A front electrode layer 21 is formed on the transparent conductive layer 22.

Here, the substrate 27 is a flexible alloy of aluminum and magnesium (Al—Mg alloy), in the form of foil. The substrate 27 has a thickness from about 10 μm to about 100 μm. The substrate 27 also can be, but is not limited to, Al, Mg, stainless steel, or polymer.

The back electrode layer 26 can be silver (Ag), copper (Cu), molybdenum (Mo), aluminum (Al), alloy of aluminum and copper (Al—Cu alloy), alloy of silver and copper (Ag—Cu alloy), or alloy of copper and molybdenum (Cu—Mo alloy). The back electrode layer 26 includes a connection end 261.

The p-type semiconductor layer 25 can be p-type amorphous silicon (p-a-Si). Preferably, the p-type semiconductor layer 25 is p-type amorphous silicon with hydrogen (p-a-Si:H). The p-type semiconductor layer 25 can alternatively be, but is not limited to, one of subgroup III-V compounds or subgroup II-VI compounds, such as semiconductor material doped with elemental aluminum (Al), gallium (Ga), or indium (In). The semiconductor material doped with elemental Al, Ga, or In can be aluminum gallium nitride (AlGaN) or aluminum gallium arsenide (AlGaAs).

The p-n junction layer 24 can be one of subgroup III-V compounds and or subgroup I-III-VI compounds, such as CdTe, CuInSe₂, CIGS (CuIn_{1-X}GaSe₂), etc. The p-n junction layer 24 is configured for converting photons to electron-hole pairs, resulting in the creation of an electric field.

The n-type semiconductor layer 23 is, preferably, n-type amorphous silicon (n-a-Si); and more preferably n-type amorphous silicon with hydrogen (n-a-Si:H). Alternatively, the n-type semiconductor layer 23 can be one of subgroup III-V compounds or subgroup II-VI compounds, such as semiconductor material doped with elemental nitrogen (N), phosphor (P), or arsenic (As). The semiconductor material doped with elemental N, P, or As can be gallium nitride (GaN) or gallium indium phosphide (GaInP).

The transparent conductive layer 22 can be indium tin oxide (ITO) or indium zinc oxide (IZO).

The front electrode layer 21 can be silver (Ag), copper (Cu), molybdenum (Mo), aluminum (Al), alloy of aluminum and copper (Al—Cu alloy), alloy of silver and copper (Ag—Cu alloy), or alloy of copper and molybdenum (Cu—Mo alloy).

The mobile phone 100 includes a rechargeable battery 42 connecting with the front electrode layer 21 and the connection end 261 of the back electrode layer 26. The rechargeable battery 42 is configured for storing electrical voltage obtained from the solar cell 20.

It is to be understood that the back cover 104 can also be highly transparent material, such as transparent resin, polymethyl methacrylate, or polyepoxy compound. In such case, the solar cell 20 is secured in the housing of the mobile phone 100 facing the back cover 104. The back cover 104 is configured for absorbing sunlight or other ambient light. When the light irradiates the back cover 104, the solar cell 20 converts the absorbed light into electrical voltage.

The powering circuit 40 includes a rechargeable element 44, a power conversion circuit 46, and a driving circuit 48.

The rechargeable element 44 can be a lithium ion battery or a nickel-metal hydride battery. The rechargeable element 44 and the rechargeable battery 42 are separately connected to the power conversion circuit 46. The power conversion circuit 46 is configured for selecting an electrical voltage source as being either the rechargeable element 44 or the rechargeable battery 42.

It is to be understood that in alternative embodiments, the rechargeable element 44 and the power conversion circuit 46 can be omitted. In such cases, the solar cell 20 is connected to the driving circuit 48 for supplying electrical voltage to the mobile phone 100 to power the functions of the mobile phone 1 00.

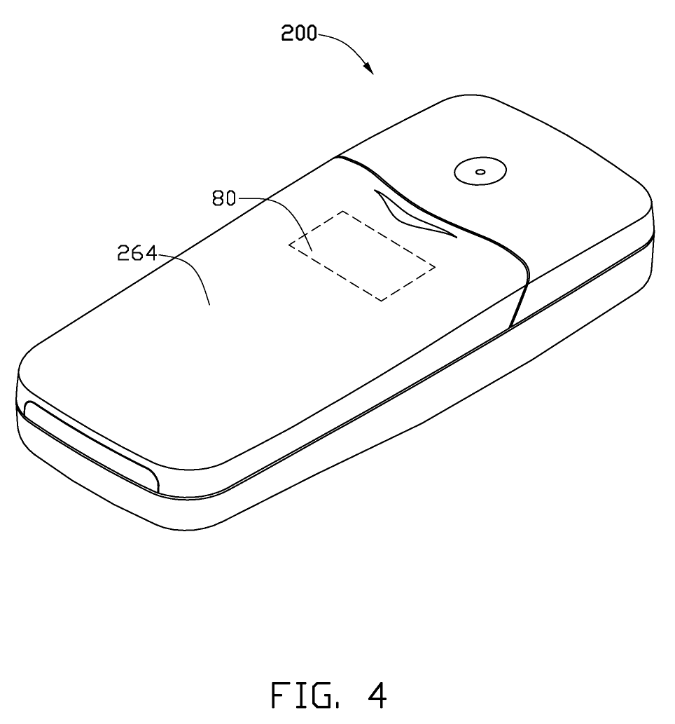

FIG. 4 is a perspective view of a second embodiment of a mobile phone 200 utilizing a solar cell 80. The mobile phone 200 differs from mobile phone 100 only in that the highly transparent section is defined on a cell cover 264. The cell cover 264 is a highly transparent material, such as transparent resin, polymethyl methacrylate, or polyepoxy compound. The solar cell 80 is secured in the housing of the mobile phone 200 facing the cell cover 264. The cell cover 264 is configured for absorbing sunlight or other ambient light. When the light irradiates the cell cover 264, the solar cell 80 converts the absorbed light into electrical voltage.

While preferred and exemplary embodiments have been described, it is to be understood that the invention is not limited thereto. To the contrary, various modifications and similar arrangements (as would be apparent to those skilled in the art) are intended to be covered. Therefore, the scope of the appended claims should be accorded the broadest interpretation so as to encompass all such modifications and similar arrangements.

What is claimed is:

1. A portable electronic device comprising:
a shell comprising a transparent section;
a powering circuit fixed in the shell; and
a solar cell fixed in the shell and located facing the transparent section and connected to the powering circuit, such that when exterior light irradiates the transparent section, the solar cell converts the absorbed light into electrical voltage which is supplied to the powering circuit to power functions of the portable electronic device.

2. The portable electronic device of claim 1, wherein the shell comprises a front cover, a back cover, and a cell cover, and the transparent section is defined at one of the front cover, the back cover, and the cell cover.

3. The portable electronic device of claim 2, wherein the transparent section comprises material selected from the group consisting of transparent resin, polymethyl methacrylate, and polyepoxy compound.

4. The portable electronic device of claim 1, wherein the portable electronic device is a mobile phone.

5. The portable electronic device of claim 1, further comprising a rechargeable battery connected with the solar cell, the rechargeable battery configured for storing electrical voltage obtained from the solar cell.

6. The portable electronic device of claim 5, wherein the powering circuit comprises a rechargeable element and a power conversion circuit, wherein the rechargeable element and the rechargeable battery are separately connected to the power conversion circuit, and the power conversion circuit is configured for selecting an electrical voltage source as being either the rechargeable element or the rechargeable battery.

7. The portable electronic device of claim 1, wherein the solar cell comprises a substrate having a first surface, a back electrode layer, a p-type semiconductor layer, a p-n junction layer, an n-type semiconductor layer, a transparent conductive layer, and a front electrode layer, the back electrode layer is formed on the first surface of the substrate, the p-type semiconductor layer is formed on the back electrode layer, the p-n junction layer is formed on the p-type semiconductor layer, the n-type semiconductor layer is formed on the p-n junction layer, the transparent conductive layer is formed on the n-type semiconductor layer, and the front electrode layer is formed on the transparent conductive layer.

8. The portable electronic device of claim 7, wherein the substrate is flexible material.

9. The portable electronic device of claim 1, wherein the powering circuit comprises a driving circuit, and the solar cell is connected to the driving circuit for supplying electrical voltage to the portable electronic device to power the functions of the portable electronic device.

10. A solar-powered portable electronic device comprising:
a shell comprising a transparent window;
a powering circuit housed in the shell; and
a solar cell housed in the shell and located adjacent the transparent window and connected to the powering circuit, wherein the solar cell is capable of converting the absorbed light into electrical voltage which is supplied to the powering circuit to power functions of the solar-powered portable electronic device when ambient light passes through the transparent window.

11. The solar-powered portable electronic device of claim 10, wherein the shell comprises a front cover, a back cover, and a cell cover, and the transparent window is defined at one of the front cover, the back cover, and the cell cover.

12. The solar-powered portable electronic device of claim 11, wherein the transparent window comprises material selected from the group consisting of transparent resin, polymethyl methacrylate, and polyepoxy compound.

13. The solar-powered portable electronic device of claim 10, wherein the solar-powered portable electronic device is a mobile phone.

14. The solar-powered portable electronic device of claim 10, further comprising a rechargeable battery connected with the solar cell, the rechargeable battery configured for storing electrical voltage obtained from the solar cell.

15. The solar-powered portable electronic device of claim 14, wherein the powering circuit comprises a rechargeable element and a power conversion circuit, wherein the rechargeable element and the rechargeable battery are separately connected to the power conversion circuit, and the power conversion circuit is configured for selecting an electrical voltage source as being either the rechargeable element or the rechargeable battery.

16. The solar-powered portable electronic device of claim 10, wherein the solar cell comprises a substrate having a first surface, a back electrode layer, a p-type semiconductor layer, a p-n junction layer, an n-type semiconductor layer, a transparent conductive layer, and a front electrode layer, the back electrode layer is formed on the first surface of the substrate, the p-type semiconductor layer is formed on the back electrode layer, the p-n junction layer is formed on the p-type semiconductor layer, the n-type semiconductor layer is formed on the p-n junction layer, the transparent conductive layer is formed on the n-type semiconductor layer, and the front electrode layer is formed on the transparent conductive layer.

17. The solar-powered portable electronic device of claim 16, wherein the substrate is flexible material.

18. The solar-powered portable electronic device of claim 10, wherein the powering circuit comprises a driving circuit, and the solar cell is connected to the driving circuit for supplying electrical voltage to the portable electronic device to power the functions of the portable electronic device.
